(19) United States
(12) Patent Application Publication
(10) Pub. No.: US 2010/0310770 A1
(43) Pub. Date: Dec. 9, 2010

(54) Process for synthesizing a thin film or composition layer via non-contact pressure containment

(76) Inventors: Baosheng Sang, Austin, TX (US); Louay Eldada, Austin, TX (US); Abner Lim, Singapore (SG); Matthew Taylor, West Simsbury, CT (US)

Correspondence Address: Allen R. Kipnes, Esq.;Watov & Kipnes, P.C., P.O. Box 247, Princeton Junction, NJ, 08550, US

(21) Appl. No.: 12/661,923

(22) Filed: Mar. 26, 2010

Related U.S. Application Data
(60) Provisional application No. 61/217,909, filed on Jun. 5, 2009.

(51) Int. Cl. C23C 16/44; B05D 3/02; B05D 3/00

(52) U.S. Cl. 427/255.23; 427/372.2; 427/248.1; 427/294

(57) ABSTRACT

A process for synthesizing a thin film or composition layer from a plurality of precursor layers supported on a substrate, includes exposing the plurality of precursor layers to non-contact pressure, and heating the plurality of precursor layers under the non-contact pressure to a reaction temperature sufficient to promote the formation of the film or composition layer.

### RELATED APPLICATION

This Application claims the benefit of priority from U.S. Provisional Patent Application Ser. No. 61/217,909, entitled “Synthesis of Films Using Precursor Layers and Non-contact Pressure Containment,” filed Jun. 5, 2009.

### FIELD OF THE INVENTION

The present invention relates to a process for synthesizing a film or composition layer via non-contact pressure containment.

### BACKGROUND OF THE INVENTION

Thin films of materials are used in various applications. For example, in applications where the thin film is electrically active, the electrical activity varies depending on the nature of the layer. Films composed of excellent absorber materials such as Cu, In, Ga, Se and S which are generally referred to as CIGS(S), or Cu(In,Ga)(S,Se)₂ or CuIn₁₋ₓ Gaₓ(S_{y}Se_{1-y})ₖ (where 0≦x≦1, 0≦y≦1 and k is approximately 2) have been employed for application in optoelectronic devices including photovoltaic devices such as solar cells.

One technique for forming Cu(In,Ga)(S,Se)₂ type thin films for solar applications involves depositing a first precursor layer of (In,Ga)_{y}(S,Se)_{1-y} on a first substrate and depositing a film containing a second precursor layer of CuₓSe (where 1≦x≦2) on a second substrate, and mechanically exerting pressure so that the first and second precursor layers can contact each other and directly interact. The contact is made to establish and maintain a planar interaction front. Heat is then applied to the first and second precursor layers under pressure to form a desired final film or composition layer. The resulting film or composition layer is incorporated into a photovoltaic device as an absorber layer. The final film or composition layer may be further processed to tailor the defect structure and/or improve performance. This technique, however, lacks fine control over reaction thermodynamics and material grading profile on the rigid substrate due to the need to apply sufficient heat to make at least one of the substrates mechanically compliant as to establish intimate contact between the precursor layers at the atomic scale, thereby partially reacting the precursors before full contact is achieved.

In view of the foregoing problems, there is a need for a process for synthesizing a film or composition layer via non-contact pressure containment, which provides precise control over the reaction thermodynamics and precise material grading profiles across the film thickness. In this manner, the process achieves a film or composition layer of favorable crystalline structure, nanostructure and desirable electronic properties, especially for use in photovoltaic applications.

### SUMMARY OF THE INVENTION

The present invention relates generally to a process for synthesizing a film or composition layer via non-contact pressure containment. The process of the present invention includes exposing a plurality of precursor layers to non-contact pressure, and then heating the plurality of precursor layers under the non-contact pressure to a reaction temperature sufficient to promote the formation of the thin film or composition layer. In one embodiment, the process of the present invention facilitates the synthesis of films or composition layers of desired crystalline structure, nanostructure and electronic properties using precursor layers deposited on a substrate, and non-contact pressure containment. In particular, the process of the present invention provides two or more precursor layers deposited in a stacked or laminate arrangement on a substrate. The process of the present invention promotes a chemical and/or physical interaction between adjacent precursor layers to produce the resulting film or composition layer.

The term “non-contact pressure” is intended to refer to any pressure exerted on the precursor layers without physical contact with a solid pressure imposing material. This contact pressure may be generated by any suitable means including, but not limited to, directly increasing the fluid pressure (e.g., gas pressure) in fluid communication with the plurality of precursor layers, or placing a vaporizable material in association with the plurality of precursor layers within a closed volume and vaporizing the vaporizable material to generate the non-contact pressure within the closed volume.

The precursor layers may be deposited on the substrate through vacuum deposition techniques, atmospheric-pressure deposition, and the like. Examples of vacuum deposition techniques include, but are not limited to, chemical vapor deposition (CVD), atomic layer deposition (ALD), chemical solution deposition (CSD), plating, physical vapor evaporation (PVD), and the like. Examples of PVD processes include, but are not limited to, thermal evaporation, electron-beam evaporation, ion beam deposition (IBD), molecular beam epitaxy (MBE), pulsed laser deposition, sputtering, and the like. Examples of atmospheric-pressure deposition include, but are not limited to, ultrasonic or pneumatic atomization spraying, inkjet spraying, direct writing, screen printing, slot die extrusion coating, and the like.

In one aspect of the present invention, there is provided a process for synthesizing a thin film or composition layer from a plurality of precursor layers supported on a substrate, which comprises the steps of:

a) exposing the plurality of precursor layers to non-contact pressure; and

b) heating the plurality of precursor layers under the non-contact pressure to a reaction temperature sufficient to promote the formation of the film or composition layer.

### BRIEF DESCRIPTION OF THE DRAWINGS

The following drawings are illustrative of embodiments of the present invention and are not intended to limit the invention as encompassed by the claims forming part of the application.

FIG. 1 is an assembly view of a reaction containment assembly or reactor with a plurality of precursor layers supported on a substrate in accordance with one embodiment of the present invention; and

FIG. 2 is a cross sectional view of the reaction containment assembly with the precursor layers and an optional precursor layer disposed on an inside surface of the reaction containment assembly in accordance with one embodiment of the present invention.

### DETAILED DESCRIPTION OF THE INVENTION

The present invention is generally directed to a process for synthesizing a film or composition layer via non-contact pressure containment. The process of the present invention includes exposing a plurality of precursor layers to non-contact pressure, and then heating the plurality of precursor layers under the non-contact pressure to a reaction temperature sufficient to promote the formation of the thin film or composition layer. The process of the present invention facilitates the synthesis of films or composition layers of desired crystalline structure, nanostructure and electronic properties using precursor layers deposited on a substrate and non-contact pressure containment.

The process of the present invention provides for two or more precursor layers deposited in a stacked or laminate arrangement on a substrate. The process of the present invention further promotes interaction between adjacent precursor layers to produce the resulting film or composition layer. The interaction between precursor layers can be chemical (e.g., reactants forming a product) and/or physical (e.g., two polymers intermingling to form a copolymer or two metals diffusing together to form a solid solution).

The term “non-contact pressure” is intended to refer to any pressure exerted on the precursor layers without physical contact with a solid pressure imposing material. This contact pressure may be generated by any suitable means including, but not limited to, directly increasing the fluid pressure (e.g., gas pressure) in fluid communication with the plurality of precursor layers, or placing a vaporizable material in association with the plurality of precursor layers within a closed volume and vaporizing the vaporizable material to generate the non-contact pressure within the closed volume.

The present process overcomes the problems associated with processes where material deposition of the precursors and reaction between the precursors occurs simultaneously. The present process separates the material deposition and reaction process into two discrete steps for improved management of the process requirements for each step. This facilitates better control of the composition, structure and deposition of the precursor layers on a substrate, and optimization of the chemical and/or physical reactions forming the final film or composition layer (e.g., product layer).

The process of the present invention will be described in context of the fabrication of a semiconductor layer, coating or film for use in, for example, a photovoltaic device and/or system. However, it will be understood that the process of the present invention can be used in various applications including, but not limited to, the fabrication of a composition layer, coating or film that may be used in a subassembly, which in turn may be used in a larger assembly, or the fabrication of a superconductor layer, coating or film for use in, for example, an electronic device and/or system.

In one embodiment of the present invention, a process for synthesizing a thin film or composition layer from a plurality of precursor layers supported on a substrate, where the process includes the steps of exposing the plurality of precursor layers to non-contact pressure as defined herein, and heating the plurality of precursor layers under the non-contact pressure to a reaction temperature sufficient to promote the formation of the film or composition layer.

Each of the precursor layers is selected from a precursor material that can effectively interact with the other precursor layer to form a desirable product layer. The precursor layers are preferably selected from the elemental series of the periodic table including Group I elements, Group III elements, Group VI elements and combinations thereof. In a more preferred embodiment, the precursor layer is selected from indium, gallium, selenium, copper, sulfur, sodium, and combinations thereof. Each of the precursor layers may be composed of a form selected from a chemical element, a binary compound, a ternary compound, a multinary compound, or combinations thereof.

In a preferred embodiment of the present invention, the reaction temperature is the temperature selected at which physical and/or chemical interaction between the precursor layers is initiated to yield a film or composition layer. The reaction temperature is typically at least 100° C., more typically from about 300° C. to 1000° C., and most typically from about 400° C. to 700° C.

In a preferred embodiment of the present invention, the non-contact pressure is the pressure selected at which physical and/or chemical interaction between the precursor layers is initiated to yield the film or composition layer. Preferably, the non-contact pressure is at least 50 Torr, more preferably from about 100 to 700 Torr, and most preferably from about 200 to 600 Torr.

The precursor layers may be deposited on the substrate through vacuum deposition techniques, atmospheric-pressure deposition, and the like. Examples of vacuum deposition techniques include, but are not limited to, chemical vapor deposition (CVD), atomic layer deposition (ALD), chemical solution deposition (CSD), plating, physical vapor evaporation (PVD), and the like. Examples of PVD processes include, but are not limited to, thermal evaporation, electron-beam evaporation, ion beam deposition (IBD), molecular beam epitaxy (MBE), pulsed laser deposition, sputtering, and the like. Examples of atmospheric-pressure deposition include, but are not limited to, ultrasonic or pneumatic atomization spraying, inkjet spraying, direct writing, screen printing, slot die extrusion coating, and the like.

In one embodiment of the present invention, the non-contact pressure may be generated via increasing the fluid pressure within a closed volume through introduction of the corresponding fluid in association with the plurality of precursor layers. The fluid may be a liquid or gas. Preferably the fluid is a gas.

In another embodiment of the present invention, the non-contact pressure may be generated by adding a vaporizable material in association with the plurality of precursor layers within a closed volume, and vaporizing the vaporizable material within the closed volume to generate the non-contact pressure. This may be achieved by heating the vaporizable material to a temperature sufficient to form a vapor therefrom.

The vaporizable material may be selected from a solid, a liquid or combinations thereof. The vaporizable material may also be selected from any suitable material capable of vaporizing under conditions compatible with formation of the film or composition layer from the precursor layers, and does not adversely affect the reaction between the precursor layers or the composition of the final product. It will be understood that the vaporizable material may be incorporated as part of the plurality of precursor layers or placed in proximity to the precursor layers within the closed volume. In a preferred embodiment of the present invention, the vaporizable material is selected from the same material used to form the plurality of precursor layers.

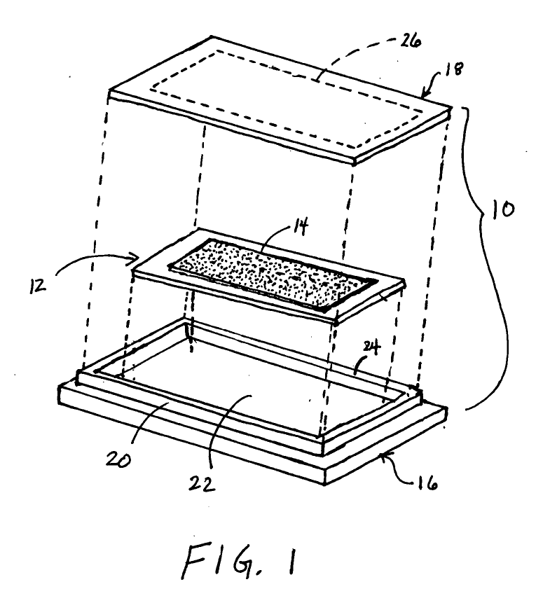

Referring to FIG. 1, a reaction containment assembly or reactor 10 containing a substrate 12 having a plurality of precursor layers 14 supported thereon, is shown for one embodiment of the present invention. The substrate 12 may be selected from any suitable refractory material such as, for example, glass. The plurality of precursor layers 14 are deposited onto the top surface of the substrate 12 via any suitable deposition process including, but not limited to, vacuum deposition techniques and atmospheric-pressure deposition techniques.

The reactor 10 includes a base portion or sample carrier 16 and an upper portion or cover plate 18. The reactor 10 is composed of a material or a combination of materials exhibiting mechanical and thermal properties suitable for sustaining the necessary non-contact pressures therein, and withstanding the conditions associated with initiating the subsequent reaction of the precursor layers 14 including high temperatures. Such reactor materials may be selected from graphite, titanium, steel, and the like. The sample carrier 16 includes a sidewall 20 extending along the periphery thereof and defining a central area 22. The central area 22 is configured to receive and retain the substrate 12 therein.

The cover plate 18 is configured for placement on the top end 24 of the sidewall 20 of the sample carrier 16. When placed on the sample carrier 16, the cover plate 18 encloses the substrate 12 within the central area 22 of the reactor 10. The cover plate 18 and the top end 24 of the sidewall 20 form a tight seal therebetween. Optionally, the cover plate 18 includes a vaporizable material layer 26 composed of a vaporizable material. The vaporizable material may be selected from indium, gallium, selenium, copper, sulfur, sodium, and combinations thereof, and deposited thereon via a suitable deposition process. When the cover plate 18 is mounted on the sample carrier 16, the optional vaporizable material layer 26 is maintained proximal to and spaced apart from the plurality of precursor layers 14 within the central area 22 of the reactor 10. The vaporizable material layer 26 provides a source of vapor effective for generating the non-contact pressure within the reactor 10 as will be described herein.

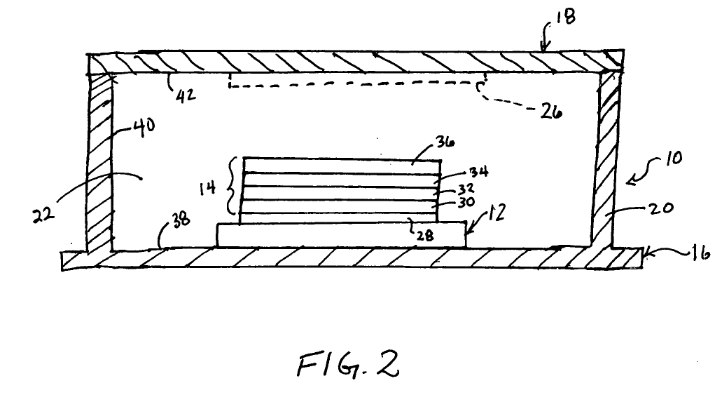

Referring to FIG. 2, the reactor 10 includes a bottom interior surface 38, a side interior surface 40 and a top interior surface 42 for defining the central area 22. In one embodiment of the present invention, the substrate 12 is disposed on the bottom interior surface 38 within the central area 22. The substrate 12 includes an optional base layer 28 of, for example, molybdenum, a first layer 30 of a precursor material such as, for example, indium gallium selenide overlaying the base layer 28, a second layer 32 of a precursor material such as, for example, copper selenide overlaying the first layer 30, a third layer 34 of a precursor material such as, for example, indium gallium selenide overlaying the second layer, and a fourth layer 36 of a precursor material such as, for example, selenium overlaying the third layer 34. The cover plate 18 optionally includes a vaporizable material layer 26 of a material which is typically compatible with the precursor materials used in the first through fourth layers. A suitable vaporizable material for use in this example is indium gallium selenide. The optional vaporizable material layer 26 may be disposed on the bottom interior surface 38 or side interior surface 40.

The reactor 10 is placed into a heating vacuum chamber. The substrate 12 is heated in the heating chamber to a reaction temperature, which induces the plurality of precursor layers 14 to react with one another through physical and/or chemical interactions as described above. The reaction temperature is typically at least 100° C., more typically from about 300° C. to 1000° C., and most typically from about 400° C. to 700° C.

The plurality of precursor layers 14 is exposed to non-contact pressure at the reaction temperature through vaporization of the vaporizable material layer 26. In the absence of or in addition to the optional vaporizable material layer 26, one of the precursor layers may be used as the vaporization material. A tight seal is made between the cover plate 18 and the sidewall 20 of the sample carrier 16 to maintain the non-contact pressure within the reactor 10. This is achieved by adjusting the pressure of the heating vacuum chamber by supplying an inert gas such as nitrogen, argon and the like, to produce a pressure of from about 100 Torr to 600 Torr within the reaction chamber. The resulting chamber pressure exerts a force on the reactor 10, which tightens the seal between the cover plate 18 and the sidewall 20 and substantially maintains the non-contact pressure within the central area 22 of the reactor 10. It will be understood that the source of the pressure increasing vapor may be disposed as one of the components of the plurality of precursor layers 14, on the bottom interior surface 38, the side interior surface 40 and/or the top interior surface 42.

In an alternative embodiment of the present invention, the tight seal between the cover plate 18 and the sidewall 20 of the sample carrier 16 may be achieved clamping a platen of a mechanical press down onto the cover plate 18. The platen applies a mechanical pressure on the cover plate 18 of the reactor 10 to ensure that the non-contact pressure is maintained within the reactor 10. The mechanical pressure is from about from about 1 bar to 10 bar, and preferably from about 6 bar to 8 bar.

The substrate 12 is then cooled to yield a thin film or composition layer for one embodiment of the present invention. The substrate 12 may be cooled down to a temperature of from about 0° C. to 300° C., and preferably 20° C. to 50° C., by flowing an inert gas (e.g., nitrogen, argon) through the heating vacuum chamber at a pressure of about 100 Torr to 600 Torr. Alternatively, a water-cooled plate may be utilized to cool the substrate 12 in place of the inert gas or optionally in the presence of the inert gas.

### EXAMPLES

### Example 1

### Thin Film Produced Via Non-Contact Pressure Using an Inert Gas

A thin laminate of precursor layers is deposited on a glass substrate via vacuum deposition process. The laminate includes about 400 nm of molybdenum as a base layer, about 1000 nm of indium gallium selenide as a first layer overlaying the base layer, about 500 nm of copper selenide as a second layer overlaying the first layer, about 150 nm of indium gallium selenide as a third layer overlaying the second layer, and about 100 nm of selenium as a fourth layer overlaying the third layer. A reaction containment assembly or reactor, having a base portion or sample carrier and an upper portion or cover plate, is obtained. The sample carrier includes a sidewall extending along the periphery thereof and defining a central area.

The glass substrate with the laminate side up is placed within the central area of the sample carrier. A layer of about 500 nm of indium gallium selenide is deposited as a vaporizable material via vacuum deposition process on a middle portion of the cover plate. The cover plate is then placed on top of the sample carrier completely enclosing the glass substrate and the vaporizable material on the cover plate within the central area of the reaction containment assembly. When pressure exterior to the reaction containment assembly is greater than the central area, a hermetic seal is formed between the sidewall of the sample carrier and the cover plate. The indium gallium selenide layer on the cover plate is maintained spaced apart from the laminate on the glass substrate.

The reaction containment assembly is placed into the chamber of a vacuum pressure oven or furnace. The chamber of the oven is evacuated to a pressure of about 10⁻³ Torr. The glass substrate within the reaction containment assembly is heated to a temperature of about 250° C. Thereafter, the chamber is filled with nitrogen gas and pressurized to a reaction pressure of about 400 Torr to ensure a good seal between the sample carrier and the cover plate. The glass substrate within the reaction containment assembly is heated to a reaction temperature of about 575° C. Using a water-cooled plate, the glass substrate is then cooled in the presence of nitrogen gas to a temperature of about 50° C. to yield a thin film for one embodiment of the present invention.

### Example 2

### Thin Film Produced Via Non-Contact Using a Mechanical Press

A thin laminate of precursor layers is deposited on a glass substrate via vacuum deposition process. The laminate includes about 800 nm of molybdenum as a base layer, about 1000 nm of indium gallium selenide as a first layer overlaying the base layer, about 500 nm of copper selenide as a second layer overlaying the first layer, about 150 nm of indium gallium selenide as a third layer overlaying the second layer, and about 100 nm of selenium as a fourth layer overlaying the third layer. A reaction containment assembly or reactor as described in Example 1 is obtained.

The glass substrate with the laminate side up is placed within the central area of the sample carrier. A layer of about 500 nm of indium gallium selenide is deposited as a vaporizable material via vacuum deposition process on a middle portion of the cover plate. The cover plate is placed on top of the sample carrier completely enclosing the substrate and the vaporizable material on the cover plate within the central area of the reaction containment assembly. When pressure exterior to the reaction containment assembly is greater than the central area, a hermetic seal is formed between the sidewall of the sample carrier and the cover plate. The indium gallium selenide layer on the cover plate is maintained spaced apart from the laminate on the substrate.

The reaction containment assembly is placed into the chamber of a vacuum pressure oven or furnace. A platen of a mechanical press is positioned on the cover plate of the reaction containment assembly. The chamber of the oven is evacuated to a pressure of about 10⁻⁵ Torr. The substrate within the reaction containment assembly is heated to a temperature of about 150° C. Thereafter, the platen applies a mechanical pressure of about 7 bar onto the cover plate to ensure a good seal between the sample carrier and the cover plate. The substrate within the reaction containment assembly is heated to a reaction temperature of about 600° C. Thereafter, the mechanical pressure exerted by the platen is removed. The substrate is then cooled by flowing argon gas at a pressure of about 400 Torr through the oven chamber to a temperature of about 50° C. to yield a thin film for one embodiment of the present invention.

The foregoing discussion discloses and describes merely exemplary embodiments of the present invention. One skilled in the art will readily recognize from such discussion, and from the accompanying drawings and claims, that various changes, modifications and variations can be made therein without departing from the spirit and scope of the invention as defined in the following claims.

What is claimed is:

1. A process for synthesizing a thin film or composition layer from a plurality of precursor layers supported on a substrate, said process comprising the steps of:
a) exposing said plurality of precursor layers to non-contact pressure; and
b) heating said plurality of precursor layers under said non-contact pressure to a reaction temperature sufficient to promote the formation of said film or composition layer.

2. The process of claim 1 wherein each of said plurality of precursor layers is selected from the elemental series of the periodic table consisting of Group I elements, Group III elements, Group VI elements and combinations thereof.

3. The process of claim 1 wherein each of said plurality of precursor layers is selected from the group consisting of indium, gallium, selenium, copper, sulfur, sodium, and combinations thereof.

4. The process of claim 1 wherein each of said plurality of precursor layers is composed of a form selected from a group consisting of a chemical element, a binary compound, a ternary compound, a multinary compound, and combinations thereof.

5. The process of claim 1 wherein said reaction temperature is at least 100° C.

6. The process of claim 5 wherein the reaction temperature is from about 300° C. to 1000° C.

7. The process of claim 6 wherein the reaction temperature is from about 400° C. to 700° C.

8. The process of claim 1 wherein the non-contact pressure is at least 50 Torr.

9. The process of claim 8 wherein the non-contact pressure is from about 100 to 700 Torr.

10. The process of claim 1 wherein the non-contact pressure is fluid pressure.

11. The process of claim 10 wherein the fluid pressure is gas pressure.

12. The process of claim 1 wherein the exposing step further comprises:
enclosing the plurality of precursor layers in a closed volume; and
increasing the pressure within the closed volume to generate the non-contact pressure.

13. The process of claim 12 wherein the pressure increasing step further comprises supplying a fluid into the closed volume, whereby the pressure within the closed volume increases.

14. The process of claim 12 wherein the pressure increasing step further comprises:
adding a vaporizable material in association with the plurality of precursor layers within the closed volume; and
vaporizing the vaporizable material within the closed volume to generate the non-contact pressure.

15. The process of claim 14 wherein the vaporizing step further comprises heating the vaporizable material.

16. The process of claim 14 wherein said vaporizable material is selected from the elemental series of the periodic table consisting of Group I elements, Group III elements, Group VI elements and combinations thereof.

17. The process of claim 14 where said vaporizable material is selected from the group consisting of indium, gallium, selenium, copper, sulfur, sodium, and combinations thereof.

18. The process of claim 1 further comprising the step of depositing the plurality of precursor layers on a substrate.

19. The process of claim 18 wherein the depositing step is carried out via a process selected from the group consisting of vacuum deposition, atmospheric-pressure deposition, and a combination thereof.
